(19) United States
(12) Patent Application Publication
(10) Pub. No.: US 2026/0006731 A1
(43) Pub. Date: Jan. 1, 2026

(54) DISPLAY DEVICE AND VEHICLE

(71) Applicants: Chengdu BOE Optoelectronics Technology Co., Ltd., Chengdu, Sichuan (CN); BOE Technology Group Co., Ltd., Beijing (CN)

(72) Inventors: Yue LEI, Beijing (CN); Hong ZHU, Beijing (CN); Yue CUI, Beijing (CN); Xiaolin LIU, Beijing (CN); Sitong CHEN, Beijing (CN); Boyang SHI, Beijing (CN); Lijuan ZHAO, Beijing (CN); Yuanjie LI, Beijing (CN); Kun SHI, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/992,570

(22) PCT Filed: Apr. 16, 2024
(86) PCT No.: PCT/CN2024/088106

§ 371 Date: Jan. 9, 2025

(30) Foreign Application Priority Data
May 31, 2023 (CN) 202310632958.1

(51) Int. Cl. H05K 5/02; B60K 35/22

(52) U.S. Cl. CPC H05K 5/0217; B60K 35/223

(57) ABSTRACT

A display device includes a support shell, a roller, a first support plate, a second support plate, at least one group of track support assemblies, and a flexible display panel. A plurality of support bars arranged in an array between the first support plate and the second support plate. A first planar display portion is fixedly connected to the first support plate, a second planar display portion is fixedly connected to the second support plate, and a curled display portion is in contact with at least part of the plurality of support bars but is not connected to the at least part of the plurality of support bars.

### CROSS-REFERENCE TO RELATED APPLICATIONS

The present disclosure is a US national stage of international application No. PCT/CN2024/088106, filed on Apr. 16, 2024, which claims priority to Chinese Patent Application No. 202310632958.1, filed on May 31, 2023, and entitled “DISPLAY DEVICE AND VEHICLE”, the entire content of each is incorporated herein by reference.

### TECHNICAL FIELD

The present disclosure relates to the field of display technology, and in particular to a display device and a vehicle.

### BACKGROUND

Currently, a display device can use a flexible display panel as a display screen. Compared with a traditional display panel, the flexible display panel has advantages of being deformable, bendable and more flexible and so on.

The display device typically includes a flexible display panel, a support component, and a driving structure. A back of the flexible display panel is fixedly connected to the support component, and the support component and the flexible display panel can be unfolded or scrolled up under the driving structure to enable the display device to have an unfolded state and a contracted state, thereby realizing the function of adjusting the size of the display surface of the display device.

The flexible display panel in the above-described display device has its own internal stress, which results in an undesirable phenomenon of unevenness in some areas in the display panel, and in turn results in a poor display effect of the display device.

### SUMMARY

Embodiments of the present disclosure provide a display device and a vehicle. The problem of poor display effect of a flexible display panel in a display device in the prior art can be solved, and the described technical solutions are as follows.

In one aspect, a display device is provided. The display device includes:
a support shell, where the support shell includes a first shell and a second shell, the first shell and the second shell are connected to each other, and an angle between the first shell and the second shell is less than 180°;
a roller, where the roller is disposed between the first shell and the second shell, and the roller is rotatably connected to the support shell;
a first support plate slidably connected to the first shell;
a second support plate slidably connected to the second shell;
at least one group of track support assemblies, where each of track support assemblies includes a plurality of support bars arranged in an array between the first support plate and the second support plate, the plurality of support bars are movably connected in sequence, two outermost support bars of the plurality of support bars are fixedly connected to the first support plate and the second support plate respectively, and at least part of the plurality of support bars are disposed on a side of the roller away from of the support shell; and
a flexible display panel, where the flexible display panel includes a first planar display portion and a second planar display portion, and a curled display portion disposed between the first planar display portion and the second planar display portion, the first planar display portion is fixedly connected to the first support plate, the second planar display portion is fixedly connected to the second support plate, and the curled display portion is in contact with at least part of the plurality of support bars but is not connected to the at least part of the plurality of support bars.

Optionally, each of the plurality of support bars includes a support bar body, and a first connecting member fixedly connected to each end portion of the support bar body; and
where two adjacent first connecting members in two adjacent support bars are movably connected.

Optionally, the first connecting member includes a first arc-shaped slide groove, and a first slider matching a shape of the first arc-shaped slide groove; and
for the two adjacent first connecting members, at least part of the first slider of one first connecting member is disposed within the first arc-shaped slide groove of the other first connecting member.

Optionally, the first connecting member includes a first connecting member body, a first raised portion, a second raised portion and a first connecting portion;
the first connecting member body is fixedly connected to an end portion of the support bar body; the first raised portion and the second raised portion are both fixedly connected to a side of the first connecting member body away from the support bar body, and the first arc-shaped slide groove is disposed between the first raised portion and the second raised portion; the first connecting member portion is fixedly connected to a side of the first raised portion away from the second raised portion; and the first connecting portion includes the first slider on a side of the first connecting portion close to the support bar body; and
for the two adjacent first connecting members, the second raised portion in one first connecting member is disposed between the first slider and the first raised portion in the other first connecting member.

Optionally, a first limiting protrusion is disposed on a side, close to the second raised portion, of the first raised portion, and a second limiting protrusion is disposed on a side, away from the first raised portion, of the first connecting portion; and
where in a case that a side of each of support bar bodies in two adjacent support bars facing the flexible display panel is flush with a side of the first support plate facing the flexible display panel, or is flush with the second support plate facing the flexible display panel, a first limiting protrusion in one support bar abuts against a second limiting protrusion in the other support bar.

Optionally, a surface of the first raised portion facing the second raised portion includes a first cambered surface and a second cambered surface, and a surface of the second raised portion close to the first raised portion is a third cambered surface; and
where the first arc-shaped slide groove is disposed between the first cambered surface and the third cambered surface and the second cambered surface is closer to the second raised portion than the first cambered surface.

Optionally, a surface of the second limiting protrusion away from the first raised portion is flush with a surface of the first slider away from the first raised portion; and
for the two adjacent first connecting members, the surface of the second limiting protrusion in one first connecting member that is away from the first raised portion and the surface of the first slider that is away from the first raised portion both abut against the first cambered surface of the first raised portion in the other first connecting member.

Optionally, the first connecting portion includes a fourth cambered surface that cooperates with the second cambered surface; and
for the two adjacent first connecting members, the second cambered surface of the first raised portion in one first connecting member abuts against the fourth cambered surface of the first connecting portion in the other first connecting member.

Optionally, in a case that two adjacent support bars are both disposed on a side of the roller away from the support shell, a side of the first raised portion of one support bar facing the first connecting portion abuts against a side of the first raised portion of the other support bar away from the first connecting portion.

Optionally, in a case that the two adjacent support bars are both disposed on the side of the roller away from the support shell, a side of the first connecting portion of one of the two adjacent support bars facing the flexible display panel is flush with a side of the first connecting member of the other of the two adjacent support bars facing the flexible display panel.

Optionally, the support bar body includes at least two sub-bar bodies arranged in sequence along a length direction of the support bar body, and a second connecting member disposed between the at least two adjacent sub-bar bodies, and the second connecting member is fixedly connected to an end portion of each of the at least two adjacent sub-bar bodies; and
two adjacent second connecting members in the two adjacent support bars are movably connected.

Optionally, the second connecting member includes a second arc-shaped slide groove, and a second slider matching a shape of the second arc-shaped slide groove; and
for the two adjacent second connecting members, at least part of the second slider in one second connecting member is disposed within the second cambered slide groove in the other second connecting member.

Optionally, the second connecting member includes two second connecting member bodies, a second connecting portion disposed between the two second connecting member bodies, and a third raised portion fixedly connected to one side of the second connecting portion; and
the second connecting member body is fixedly connected to an end portion of the sub-bar body close to the second connecting member; the second arc-shaped slide groove is disposed in the third raised portion, and the second slider is disposed on a side of the second connecting portion away from the third raised portion.

Optionally, the side of the second connecting portion away from the third raised portion further includes a third limiting projection, and the end portion of the sub-bar body close to the second connecting member includes a limiting groove; and
in a case that the side of each of the support bar bodies in the two adjacent support bars facing the flexible display panel is flush with the side of the first support plate facing the flexible display panel, or is flush with the side of the second support plate facing the flexible display panel, at least part of the third limiting projection in one support bar is disposed in a limiting groove in the other support bar so as to abut against the end portion of the sub-bar body in the other support bar close to the second connecting member.

Optionally, in a case that the two adjacent support bars are both disposed on a side of the roller away from the support shell, a side of the third raised portion of one support bar away from the second connecting portion abuts against a side of the second connecting portion of the other support bar away from the third raised portion.

Optionally, a side of the second connecting member facing the flexible display panel is flush with a side of the sub-bar body facing the flexible display panel.

Optionally, a first connecting member and a second connecting member of a support bar of the plurality of support bars which is closest to the first support plate are both fixedly connected to the first support plate, and a first connecting member and a second connecting member of a support bar of the plurality of support bars which is closest to the second support plate are both fixedly connected to the second support plate.

Optionally, the sub-bar body includes a first plane and a second plane disposed opposite to each other, and a third plane and a fourth plane disposed between the first plane and the second plane and disposed opposite to each other; and
the first plane is a surface of the sub-bar body facing the flexible display panel, an angle between the first plane and the third plane is an acute angle, and/or an angle between the first plane and the fourth plane is an acute angle.

Optionally, the sub-bar body includes a plurality of lightening holes, and the plurality of lightening holes pass through the first plane and the second plane.

Optionally, the sub-bar body has a plurality of lightening grooves, and the plurality of lightening grooves are distributed on at least one of the first plane, the second plane, the third plane, or the fourth plane.

Optionally, the display device includes a plurality of groups of track support assemblies, and the plurality of groups of the track support assemblies are disposed in a length direction of the roller in sequence.

Optionally, the flexible display panel includes a driving backplane, a planarization layer disposed on a side of the driving backplane, and a plurality of light-emitting devices disposed on a side of the planarization layer away from the driving backplane, and the plurality of light-emitting devices are electrically connected to the driving backplane; and
in two adjacent support bars, one support bar is rotatable relative to the other support bar, and in a case that one support bar rotates relative to the other support bar, a rotation axis of the support bar is within a surface of the planarization layer away from the driving backplane.

Optionally, the display device further includes a drive assembly, the drive assembly is fixed within the support shell, and the drive assembly is connected to at least one of the first support plate and the second support plate.

In another aspect, a vehicle is provided, and the vehicle includes:
a display device fixed in the cabin of a vehicle, and the display device is any of the display devices given above.

The technical solutions provided by embodiments of the present disclosure bring at least the following beneficial effects.

A display device may include a support shell, a roller, a first support plate, a second support plate, at least one group of track support assemblies, and a flexible display panel. A plurality of support bars are movably connected in sequence between the first support plate and the second support plate in the display device. A first planar display portion of the flexible display panel is fixedly connected to the first support plate and a second planar display portion is fixedly connected to the second support plate. The plurality of support bars disposed between the two support plates can effectively support a back of the flexible display panel and effectively reduce the probability of undesirable phenomenon of unevenness of the flexible display panel, so that the overall flatness of the flexible display panel is better and then the display effect of the display device is better. In addition, there exists a part of the support bars distributed on the side of the roller away from the support shell, and the curled display portion in the flexible display panel is in contact with the part of the support bars and is detachably arranged. In this way, when the flexible display panel is switched between the unfolded state and the contracted state, no dislocation stress is generated between the support bars and the curled display portion in the flexible display panel. That is, a pulling force caused by misalignment between the support bar and the flexible display panel when the support bar and the flexible display panel slide at the roller (the rotation radii of the support bar and the flexible display panel are different, and there may be a phenomenon of inconsistent rotation paths) is effectively avoided, so that the use reliability of the flexible display panel in the display device is ensured.

### BRIEF DESCRIPTION OF DRAWINGS

In order to more clearly illustrate the technical solutions in the embodiments of the present disclosure, the accompanying drawings to be used in the description of the embodiments will be briefly introduced below, and it will be obvious that the accompanying drawings in the following description are only some of the embodiments of the present disclosure, and other accompanying drawings can be obtained according to these drawings for the people of ordinary skill in the field without putting forth creative labor.

FIG. 1 is a schematic diagram of a switching effect between an unfolded state and a contracted state of a display device provided by an embodiment of the present disclosure;

FIG. 2 is an exploded schematic diagram of a partial structure of a display device provided by an embodiment of the present disclosure;

FIG. 3 is an assembly schematic diagram of the display device illustrated in FIG. 2;

FIG. 4 is a schematic diagram of a connection of a flexible display panel to a track support assembly and a roller;

FIG. 5 is a side view of a display device provided by an embodiment of the present disclosure;

FIG. 6 is an exploded schematic diagram of two adjacent support bars provided by an embodiment of the present disclosure;

FIG. 7 is a structural schematic diagram of a plurality of support bars illustrated in FIG. 6;

FIG. 8 is a structural schematic diagram of a plurality of support bars illustrated in FIG. 6;

FIG. 9 is a structural schematic diagram of another support bar provided by an embodiment of the present disclosure;

FIG. 10 is a side view of a first connecting member provided by an embodiment of the present disclosure;

FIG. 11 is a structural schematic diagram of a plurality of connected first connecting members;

FIG. 12 is a side view of two adjacent connected first connecting members;

FIG. 13 is a structural schematic diagram of yet another support bar provided by an embodiment of the present disclosure,

FIG. 14 is a side view of a plurality of first connecting members provided by an embodiment of the present disclosure when curled;

FIG. 15 is an effect schematic illustration, when the plurality of first connecting members illustrated in FIG. 14 are curled;

FIG. 16 is an exploded schematic diagram of a support bar body provided by an embodiment of the present disclosure;

FIG. 17 is a schematic diagram of a connection of the support bar body illustrated in FIG. 16;

FIG. 18 is an exploded schematic diagram of a second connecting member and a sub-bar body provided by an embodiment of the present disclosure;

FIG. 19 is an exploded schematic diagram of a partial structure of a plurality of support bar bodies provided by an embodiment of the present disclosure;

FIG. 20 is a partial structure of the plurality of support bar bodies illustrated in FIG. 19;

FIG. 21 is a schematic diagram of an arrangement of a plurality of track support assemblies provided by an embodiment of the present disclosure;

FIG. 22 is a structural schematic diagram of a sub-bar body provided by an embodiment of the present disclosure;

FIG. 23 is a structural schematic diagram of another sub-bar body provided by an embodiment of the present disclosure;

FIG. 24 is a structural schematic diagram of yet another sub-bar body provided by an embodiment of the present disclosure;

FIG. 25 is a structural schematic diagram of a film layer of a flexible display panel provided by an embodiment of the present disclosure;

FIG. 26 is a side view of a plurality of connected first connecting members provided by an embodiment of the present disclosure; and

FIG. 27 is a block diagram of a vehicle provided by an embodiment of the present disclosure.

By means of the foregoing accompanying drawings, definite embodiments of the present disclosure have been shown and will be described in greater detail later. These accompanying drawings and textual descriptions are not intended to limit in any way the scope of the presently conceived application, but rather to illustrate the concepts of the present disclosure for those skilled in the art by reference to particular embodiments.

### DETAILED DESCRIPTION

In order to make the purpose, technical solutions and advantages of the present disclosure clearer, the following will describe the embodiments of the present disclosure in further detail in conjunction with the accompanying drawings.

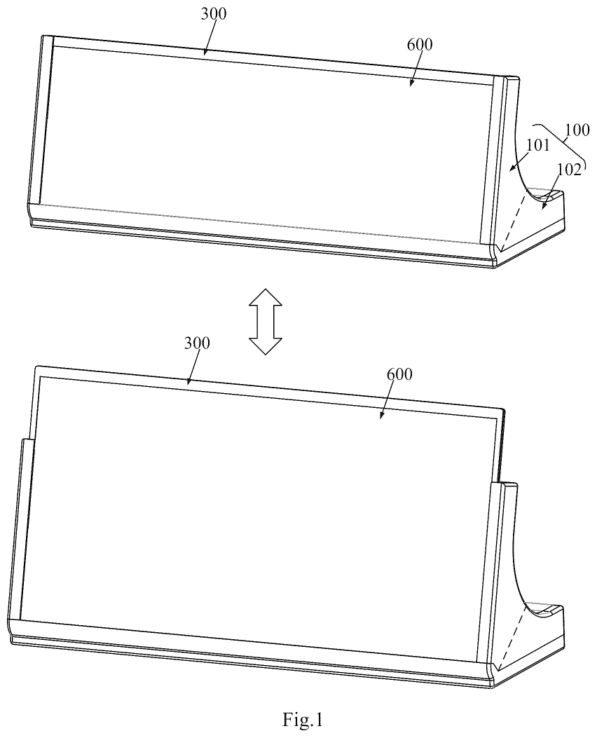

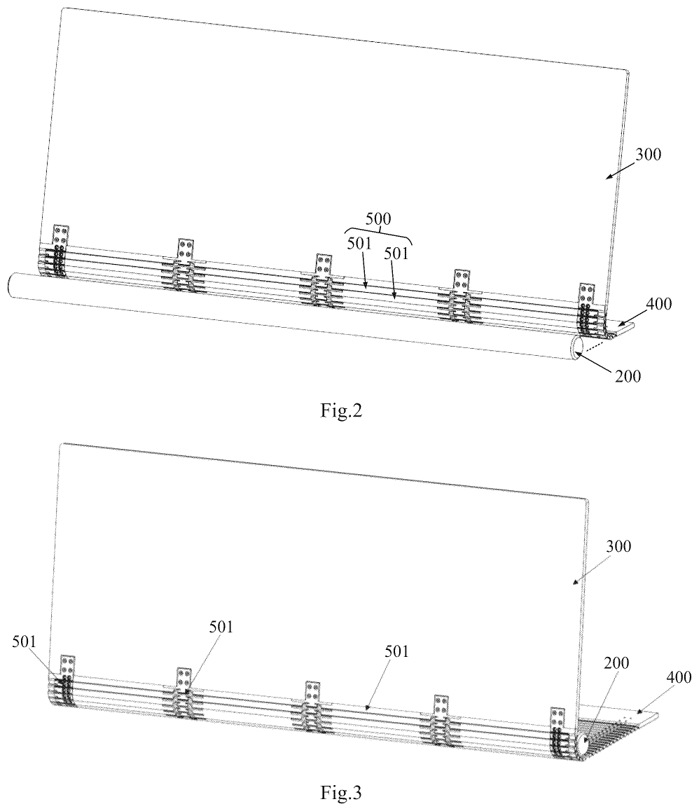

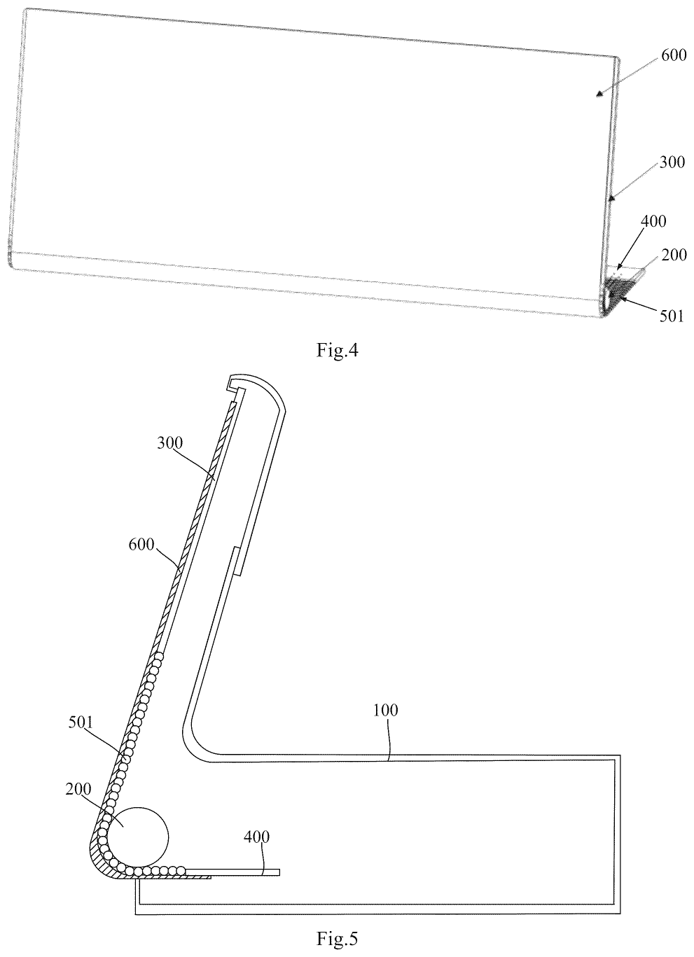

Please refer to FIGS. 1 to 5. FIG. 1 is a schematic illustration of a switching effect between an unfolded state and a folded state of a display device provided by an embodiment of the present disclosure, FIG. 2 is an exploded schematic illustration of a partial structure of a display device provided by an embodiment of the present disclosure, FIG. 3 is an assembly schematic illustration of the display device illustrated in FIG. 2, FIG. 4 is a schematic diagram of a connection of a flexible display panel to a track support assembly and a roller, and FIG. 5 is a side view of a display device provided by an embodiment of the present disclosure. The display device may include a support shell 100, a roller 200, a first support plate 300, a second support plate 400, at least one group of track support assemblies 500, and a flexible display panel 600.

The support shell 100 in the display device may include a first shell 101 and a second shell 102, the first shell 101 and the second shell 102 are connected to each other, and an angle between the first shell 101 and the second shell 102 may be less than 180 degrees.

The roller 200 in the display device may be disposed between the first shell 101 and the second shell 102, and the roller 200 may be rotatably connected to the support shell 100.

The first support plate 300 in the display device may be slidably connected to the first shell 101.

The second support plate 400 in the display device may be slidably connected to the second shell 102.

The track support assembly 500 in the display device may include a plurality of support bars 501 arranged in an array between the first support plate 300 and the second support plate 400, and the plurality of support bars 501 may be movably connected in sequence. Two outermost support bars 501 of the plurality of support bars 501 may be fixedly connected to the first support plate 300 and the second support plate 400, respectively, and at least part of the plurality of support bars 501 may be disposed on a side of the roller 200 away from the support shell 100. In the present disclosure, one of the plurality of support bars 501 that is closest to the first support plate 300 may be fixedly connected to the first support plate 300, and one of the plurality of support bars 501 that is closest to the second support plate 400 may be fixedly connected to the second support plate 400.

The flexible display panel 600 in the display device may include a first planar display portion 601 and a second planar display portion 602, and a curled display portion 603 disposed between the first planar display portion 601 and the second planar display portion 602. The first planar display portion 601 in the flexible display panel 600 may be fixedly connected to the first support plate 300, the second planar display portion 602 in the flexible display panel 600 may be fixedly connected to the second support plate 400, and the curled display portion 603 in the flexible display panel 600 may be in contact with at least part of the plurality of support bars 501 and may be detachably arranged with the at least part of the support bars 501. It is noted that the part of the flexible display panel 600 fixedly connected to the first support plate 300 is the first planar display portion 601, the part of the flexible display panel 600 fixedly connected to the second support plate 400 is the second planar display portion 602, and portions of the flexible display panel 600 disposed between the first planar display portion 601 and the second planar display portion 602 may all be curled display portion 603.

In an embodiment of the present disclosure, a plurality of support bars 501 are movably connected in sequence between the first support plate 300 and the second support plate 400 of the display device The first planar display portion 601 is fixedly connected to the first support plate 300, and the second planar display portion 602 is fixedly connected to the second support plate 400. The plurality of support bars 501 between the two support plates can be in contact with a back of the flexible display panel 600 and can effectively support the flexible display panel 600 and effectively reduce the probability of undesirable phenomenon of unevenness of the flexible display panel 600, so that the overall flatness of the flexible display panel 600 is better and then the display effect of the display device is better. In addition, there exists a part of the support bars 501 distributed on the side of the roller 200 away from the support shell 100, and the curled display portion 603 in the flexible display panel 600 is in contact with the part of the support bars 501 and is detachably arranged In this way, when the flexible display panel 600 is switched between the unfolded state and the contracted state, no dislocation stress is generated between the support bars 501 and the curled display portion 603 in the flexible display panel 600. That is, the pulling force caused by misalignment between the support bar 501 and the flexible display panel 600 when the support bar 501 and the flexible display panel 600 slide at the roller 200 (the rotation radii of the support bar 501 and the flexible display panel 600 are different, and there may be a phenomenon of inconsistent rotation paths) is effectively avoided, so that the use reliability of the flexible display panel 600 in the display device is ensured.

Exemplarily, the flexible display panel 600 in the display device is able to flexibly adjust the size of the display surface of the flexible display panel during extension and contraction, which can make the flexible display panel 600 applicable to different usage scenarios. For example, when the display device is used in a vehicle, the size of the flexible display panel being extended from the display device can be flexibly adjusted, so that the flexible display panel is applicable to different usage scenarios of the vehicle. In this way, the user's requirements for entertainment and safety can be met, and the requirement for installation space of the vehicle is low. Especially for the large-size flexible display screen, its size can be adjusted according to different usage scenarios in the vehicle environment. For example, when the vehicle is running, the flexible display is partially accommodated in the internal space of the display device, so that the display area of the flexible display screen is reduced, and the running information of the vehicle is provided by using a smaller display screen, thereby providing a good driving field of vision. When the vehicle is in an entertainment state, a larger part or all of the flexible display screen extends out of the internal space of the display device, so that the display area is increased, and the user's entertainment requirement is met.

In summary, embodiments of the present disclosure provide a display device that may include a support shell, a roller, a first support plate, a second support plate, at least one group of track support assemblies, and a flexible display panel. A plurality of support bars are movably connected in sequence between the first support plate and the second support plate in the display device. A first planar display portion of the flexible display panel is fixedly connected to the first support plate and a second planar display portion is fixedly connected to the second support plate. The plurality of support bars disposed between the two support plates can effectively support a back of the flexible display panel and effectively reduce the probability of undesirable phenomenon of unevenness of the flexible display panel, so that the overall flatness of the flexible display panel is better and then the display effect of the display device is better. In addition, there exists a part of the support bars distributed on the side of the roller away from the support shell, and the curled display portion in the flexible display panel is in contact with the part of the support bars and is detachably arranged. In this way, when the flexible display panel is switched between the unfolded state and the contracted state, no dislocation stress is generated between the support bars and the curled display portion in the flexible display panel. That is, a pulling force caused by misalignment between the support bar and the flexible display panel when the support bar and the flexible display panel slide at the roller (the rotation radii of the support bar and the flexible display panel are different, and there may be a phenomenon of inconsistent rotation paths) is effectively avoided, so that the use reliability of the flexible display panel in the display device is ensured.

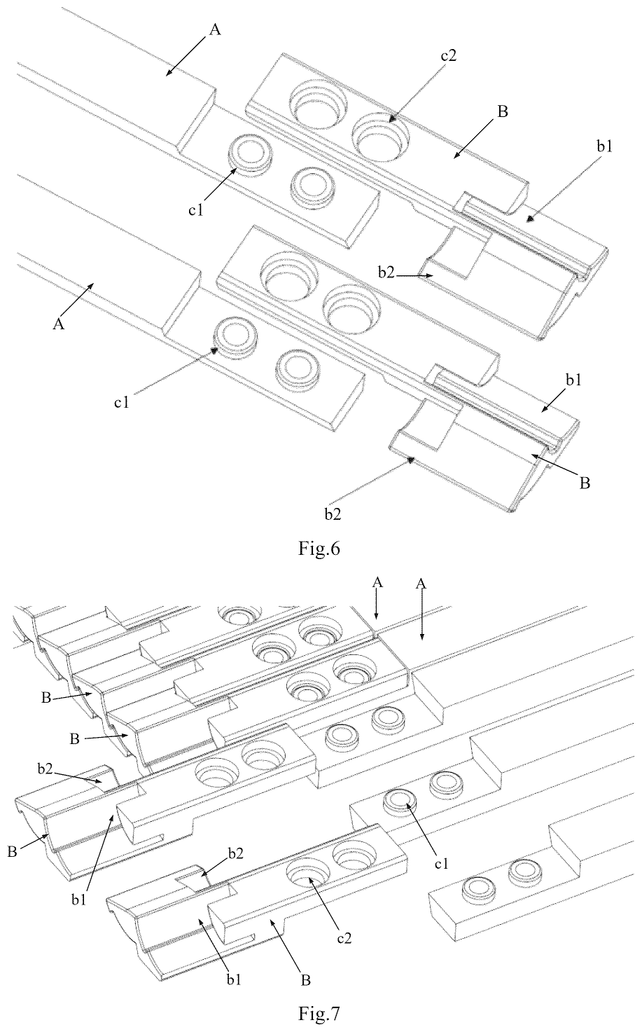

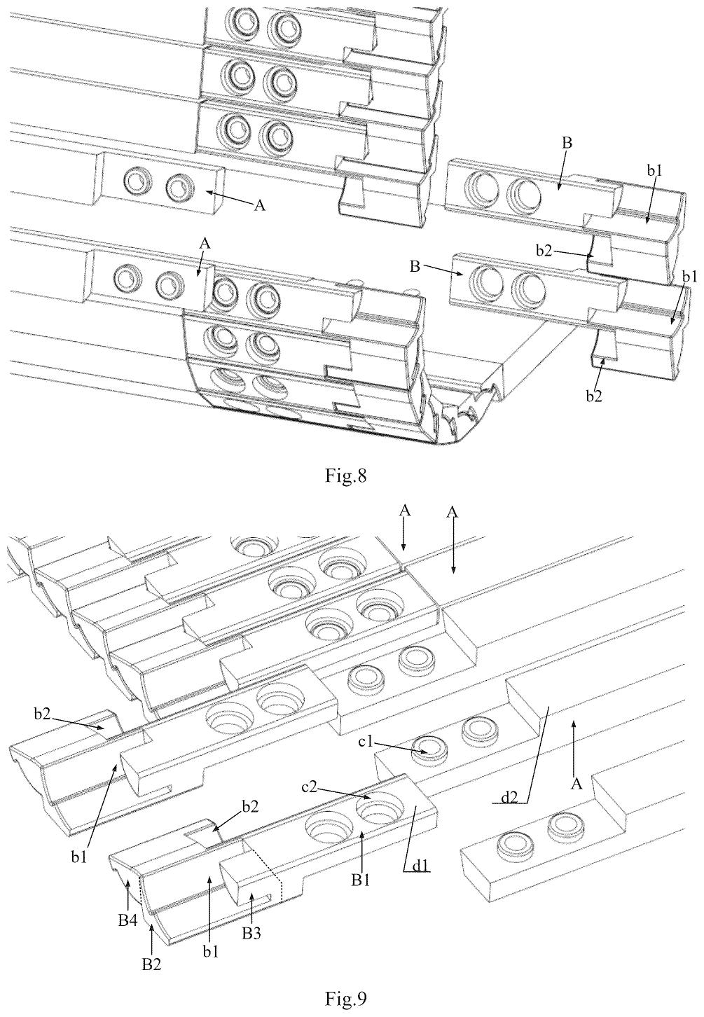

Optionally, please refer to FIG. 6, FIG. 7 and FIG. 8. FIG. 6 is an exploded schematic diagram of two adjacent support bars provided by an embodiment of the present disclosure, and FIG. 7 is a structural schematic diagram of a plurality of support bars illustrated in FIG. 6, and FIG. 8 is a structural schematic diagram of a plurality of support bars illustrated in FIG. 6. Each support bar 501 in the track support assembly 500 may include a support bar body A, and a first connecting member B fixedly connected to each end portion of the support bar body A (each end portion of the support bar body is connected to the first connecting member). Two adjacent first connecting members B of two adjacent support bars 501 are movably connected. In this case, by setting the two end portions of the support bar body A in the support bar 501 to be fixedly connected to the two first connecting members B respectively, and the two adjacent first connecting members B in the two adjacent support bars 501 to be movably connected, it can easily realize that the plurality of support bars 501 are movably connected in sequence. It should be noted that in other possible implementations, the support bar body A and the first connecting member B in the support bars 501 may be a one-piece structure.

In an embodiment of the present disclosure, as shown in FIGS. 6, 7, and 8, the first connecting member B in the support bar 501 may have a first arc-shaped slide groove b1, and a first slider b2 that matches the shape of the first arc-shaped slide groove b1. For two first connecting members B in two adjacent support bars 501, at least part of the first slider b2 in one first connecting member B may be disposed within the first arc-shaped slide groove b1 of the other first connection member B, in the first arc-shaped slide groove b1. In this case, the first arc-shaped slide groove b1 and the first slider b2 that matches the shape of the first arc-shaped slide groove b1 are arranged in the first connecting members B respectively, so that in the two adjacent support bars 501, the first slider b2 of the first connecting member B of one support bar 501 can be disposed within the first arc-shaped slide groove b1 of the first connecting member B of the other support bar 501. The display device can be disposed in the expanded and contracted states, respectively. When the display device is switched between the unfolded state and the contracted state (during this process, the first support plate and the second support plate drive both the flexible display panel and the plurality of support bars to move), the first slider b2 can slide smoothly within the first arc-shaped slide groove b1.

Optionally, please refer to FIG. 6, FIG. 7, FIG. 8, and FIG. 9. FIG. 9 is a structural schematic diagram of another support bar provided by an embodiment of the present disclosure. The first connecting member B in the support bar 501 in the display device may include a first connecting member body B1, a first raised portion B2, a second raised portion B3, and a first connecting portion B4. The first connecting member body B1 may be fixedly connected to an end portion of the support bar body A. Both the first raised portion B2 and the second raised portion B3 can be fixedly connected to a side of the first connecting member body B1 that is away from the support bar body A, and the first raised portion B2 and the second raised portion B3 can have a first arc-shaped slide groove b1 therebetween. The first connecting portion B4 can be fixedly connected to a side of the first raised portion B2 that is away from the second raised portion B3, and the first connecting portion B4 can have a first sliding block b2 on a side of the first connecting portion B4 that is close to the support bar body A. For two first connecting members B in two adjacent support bars 501, the second raised portion B3 in one first connecting member B may be disposed between the first slider b2 and the first raised portion B2 in the other first connecting member B. In this case, the first raised portion B2 and the second raised portion B3 which are configured for forming the first arc-shaped slide groove b1 are arranged in the first connecting member B, the first slider b2 is provided on the side of the first connecting portion B4 close to the body A of the support bar, and the second raised portion B3 in one first connecting member B is disposed between the first slider b2 and the first raised portion B2 in the other first connecting member B, such that it can be ensured that the two first connecting members B in the two adjacent support bars 501 do not detach from each other in the direction along the length of the support bars 501. In the present disclosure, as shown in FIG. 9, one of the first connecting member body B1 and the support bar body A may have a first positioning post c1, and the other of the first connecting member body B1 and the support bar body A may have a first positioning hole c2 cooperating with the first positioning post c1, and the first positioning hole c2 may be sleeved on the first positioning post c1. After the first connecting member body B1 is fixedly connected to the support bar body A, the side d1 of the first connecting member body B1 facing the flexible display panel 600 may be flush with the side d2 of the support bar body A facing the flexible display panel 600. In this case, the cooperation between the first positioning post c1 and the first positioning hole c2 can ensure the positional accuracy of the first connecting member body B1 and the support bar body A during assembly. In the actual assembly process, a threaded hole (not shown in the figure) can be provided on the first positioning post c1, and the first positioning bole c2, after being sleeved on the first positioning post c1, can be connected to the threaded hole by a screw to realize the connection between the first connecting member body B1 and the support bar body A.

For example, the end portion of the support bar body A may have a first positioning post c1, and the end portion of the first connecting member body B1 may have a first positioning hole c2, and after the first positioning hole c2 is sleeved on the first positioning post c1, the fixation of the first connecting member body B1 and the support bar body A may be realized through the cooperating connection of the screw and the threaded hole. It is to be noted that the first connection member body B1, the first raised portion B2, the second raised portion B3, and the first connecting portion B4 in the first connection member B may all be one-piece structures, i.e., each structure may be formed on the first connection member B by a turning processing.

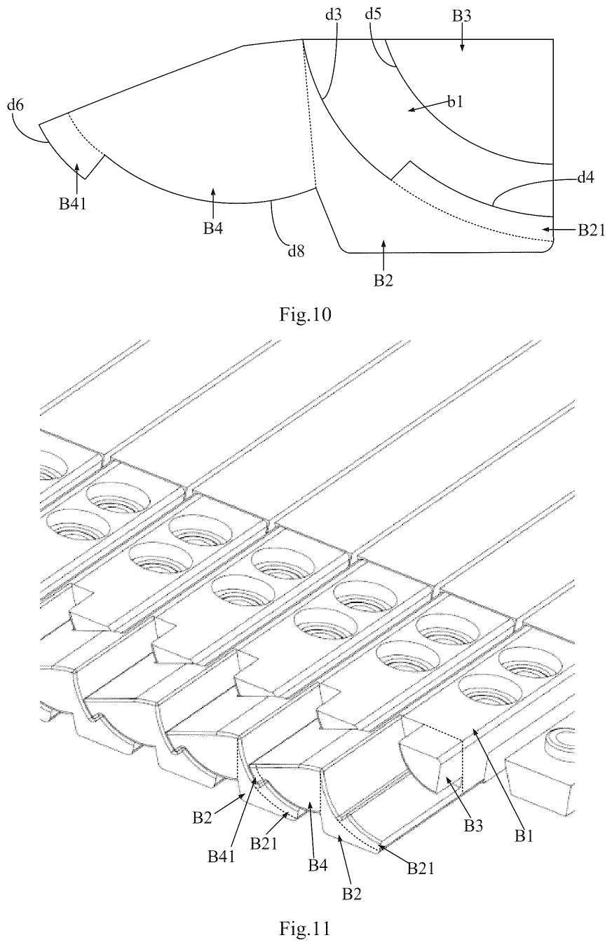

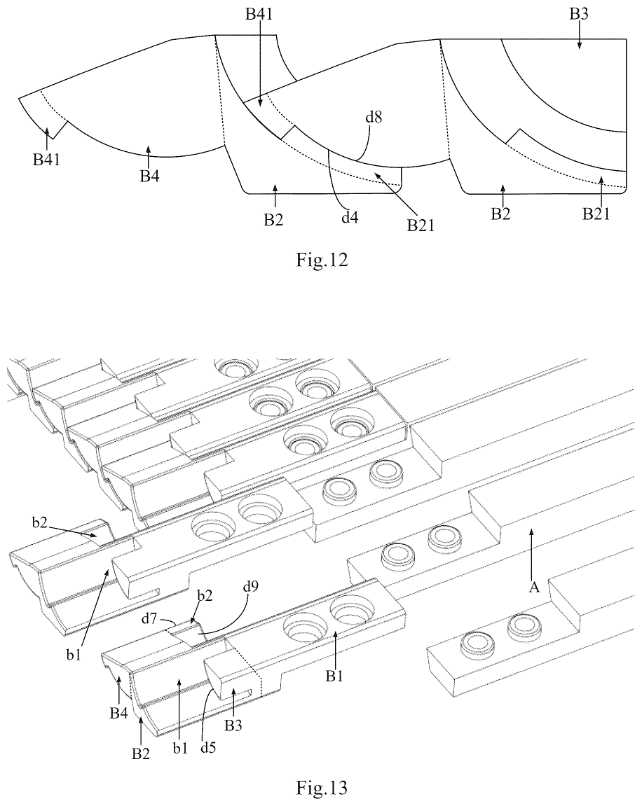

In this embodiment of the present disclosure, please refer to FIG. 10, FIG. 11 and FIG. 12. FIG. 10 is a side view of a first connecting member provided by an embodiment of the present disclosure, FIG. 11 is a structural schematic diagram of a plurality of connected first connecting members, and FIG. 12 is a side view of two adjacent connected first connecting members. The first raised portion B2 in the first connecting member B may have a first limiting protrusion B21 on a side close to the second raised portion B3, and the first connecting portion B4 may have a second limiting protrusion B41 on a side away from the first raised portion B2. When a side of both the two adjacent support bar bodies A facing the flexible display panel 600 may be flush with a side of the first support plate 300 facing the flexible display panel 600; or, when the side of both the two adjacent support bar bodies A facing the flexible display panel 600 may be flush with the side of the second support plate 400 facing the flexible display panel 600, the first limiting protrusion B21 in one of the support bars 501 abuts against the second limiting protrusion B41 in the other support bar 501. In this case, after switching of the display device between the unfolded state and the contracted state is completed, there usually exist two adjacent support bars of the plurality of support bars 501 whose support bar bodies A are both flush with the side of the first support plate 300 facing the flexible display panel 600, or there usually exist two adjacent support bars of other portion of the plurality of support bars 501 whose support bar bodies A are both flush with the side of the second support plate 400 facing the flexible display panel 600. During this switching process, the first slider b2 in one of the two adjacent support bars 501 slides in a counterclockwise direction within the first are-shaped slide groove b1 in the other support bar, and when the first slider b2 slides to a first target position, the first limiting protrusion B21 on the first raised portion B2 in one of the support bars 501 abuts against the second limiting protrusion B41 in the first connecting portion B4 in the other support bar 501. In addition, when two adjacent support bars 501 are movably connected, if one support bar 501 is subjected to a force in a direction perpendicular to the flexible display panel 600, it is possible that the first slider b2 in one support bar 501 slides within the first arc-shaped slide groove b1 in the other support bar 501. However, through the locking effect of the first limiting protrusion B21 and the second limiting protrusion B41, the first slider b2 will not slide excessively than the first arc-shaped slide groove b1. It is to be noted that the first target position may be a position where the first limiting protrusion B21 is provided in the first raised portion B2.

Optionally, as shown in FIGS. 10, 11, and 12, the first raised portion B2 in the support bar 501 facing the second raised portion B3 may include a first cambered surface d3 and a second cambered surface d4, and a side of the second raised portion B3 that is close to the first raised portion B2 may be a third cambered surface d5 The first arc-shaped slide groove b1 may be disposed between the first cambered surface d3 and the third cambered surface ds, and the second cambered surface d4 in the side of the first protruding portion B2 facing the second raised portion B3 may be closer to the second raised portion B3 than the first cambered surface d3. In the present disclosure, the second cambered surface d4 in the side of the first protruding portion B2 facing the second raised portion B3 is the side of the first limiting protrusion B21 close to the second raised portion B3. The second cambered surface d4 is closer to the second raised portion B3 than the first cambered surface d3, i.e., a distance between the second cambered surface d4 and the third cambered surface d5 is smaller than a distance between the first cambered surface d3 and the third cambered surface d5. In this case, a first arc-shaped slide groove b1 is formed between the first cambered surface d3 and the second cambered surface d4, the first slider b2 is able to slide in the first arc-shaped slide groove b1 between the two cambered surfaces and the first cambered surface d3 and the second cambered surface d4 can play a good role in limiting the sliding of the first slider b2.

In this embodiment of the present disclosure, reference is made to FIG. 10 and FIG. 13. FIG. 13 is a structural schematic diagram of yet another support bar provided by an embodiment of the present disclosure. A side d6 of the second limiting protrusion B41 away from the first raised portion B2 may be flush with a side d7 of the first slider b2 away from the first raised portion B2. For the two first connecting members B in the two adjacent support bars 501, both the side d6 of the second limiting protrusion B41 away from the first raised portion B2 in one first connecting member B and the side d7 of the first slider b2 away from the first raised portion B2 can abut with the first curved side d3 of the first raised portion B2 in the other first connecting member B. In this case, by setting the side do of the second limiting protrusion B41 away from the first raised portion B2 to be flush with the side d7 of the first slider b2 away from the first raised portion B2, and by setting both the side do of the second limiting protrusion B41 away from the first raised portion B2 in one of the two first connecting members B in the two adjacent support bars 501 and the side d7 of the first slider b2 away from the first raised portion B2 can abut with the first curved side d3 of the first raised portion B2 in the other first connecting member B, the second limit projection B41 is able to slide within the first arc-shaped slide groove b1, and the first cambered surface d3 is able to support the second limit projection B41 and the first slider b2.

Optionally, FIGS. 10 and 12, the first connecting portion B4 in the first connecting member B may have a fourth cambered surface d8 that cooperates with a second cambered surface d4 of the first raised portion B2 in the side facing the second raised portion B3. For two first connecting members B in two adjacent support bars 501, the second cambered surface d4 of the first raised portion B2 in one first connecting member B abuts against the fourth cambered surface d8 of the first raised portion B2 in the other first connecting member B. In this case, the fourth cambered surface d8 that cooperates with the second cambered surface d4 in the first raised portion B2 is arranged in the first connecting portion B4, and the second cambered surface d4 of the first raised portion B2 in one of the two first connecting members B in the adjacent two support bars 501 can abut against the fourth cambered surface d8 of the first connecting portion in the other first connecting member B, so that when the first slider b2 slides in the first arc-shaped slide groove b1, the first connecting portion B4 is effectively supported by the first raised portion B2. It is to be noted that in the present disclosure, as shown in FIG. 13, the side d9 of the first slider b2 facing the first raised portion B2 may also be an cambered surface, and for the two first connecting members B in the two adjacent support bars 501, the side d9 of the first slider b2 in one first connecting member B facing the first raised portion B2 may abut against the third cambered surface d5 of the second raised portion B3 in the other first connecting member B close to the first raised portion B2.

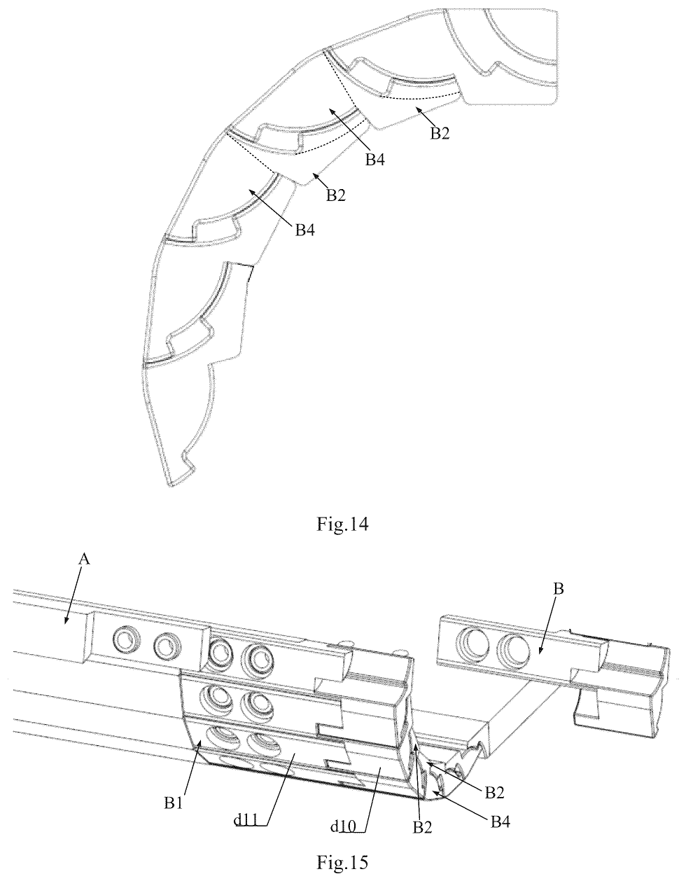

In this embodiment of the present disclosure, reference is made to FIG. 14 and FIG. 15. FIG. 14 is a side view of a plurality of first connecting members provided by an embodiment of the present disclosure when curled, and FIG. 15 is an effect schematic illustration, when the plurality of first connecting members illustrated in FIG. 14 are curled. When two adjacent support bars 501 are both located on the side of the roller 200 away from the support shell 100, one side of the first raised portion B2 in one support bar 501 facing the first connecting portion B4 in this support bar abuts against one side of the first raised portion B2 in the other support bar 501 away from of the first connecting portion B4 in this support bar in the other support bar 501. In this case, when two adjacent support bars in another portion of the plurality of support bars 501 slide at the roller 200, the first slider b2 in one of the two adjacent support bars 501 is able to slide in a clockwise direction within the first are-shaped slide groove b1 in the other support bar 501, and when the first slider b2 slides to a second target position, one side of the first protruding portion B2 facing the first connecting portion B4 abuts against one side of the first protruding portion B2 of the other support bar 501 that is away from the first connecting portion B4. It is ensured that there is no excessive relative sliding between the first slider b2 and the first arc-shaped slide groove b1. In the present disclosure, as shown in FIG. 15, when both adjacent support bars 501 can be located on the side of the roller 200 away from the support shell 200, the side d10 of the first connecting portion B4 in one support bar 501 facing the flexible display panel 600 can be flush with the side d11 of the first connecting member body B1 in the other support bar 501 facing the flexible display panel 600. In this case, when the first slider b2 in one support bar 501 slides to the second target position within the first arc-shaped slide groove b1 in the other support bar 501, the side d10 of the first connecting portion B4 in one support bar facing the flexible display panel 600 may be flush with the side d11 of the first connecting member body B1 in the other support bar 501 facing the flexible display panel 600. In this way, a support plane formed by the side d10 of the first connecting portion B4 facing the flexible display panel 600 and the side d11 of the first connecting member body B1 facing the flexible display panel 600 can provide a good support for the flexible display panel 600.

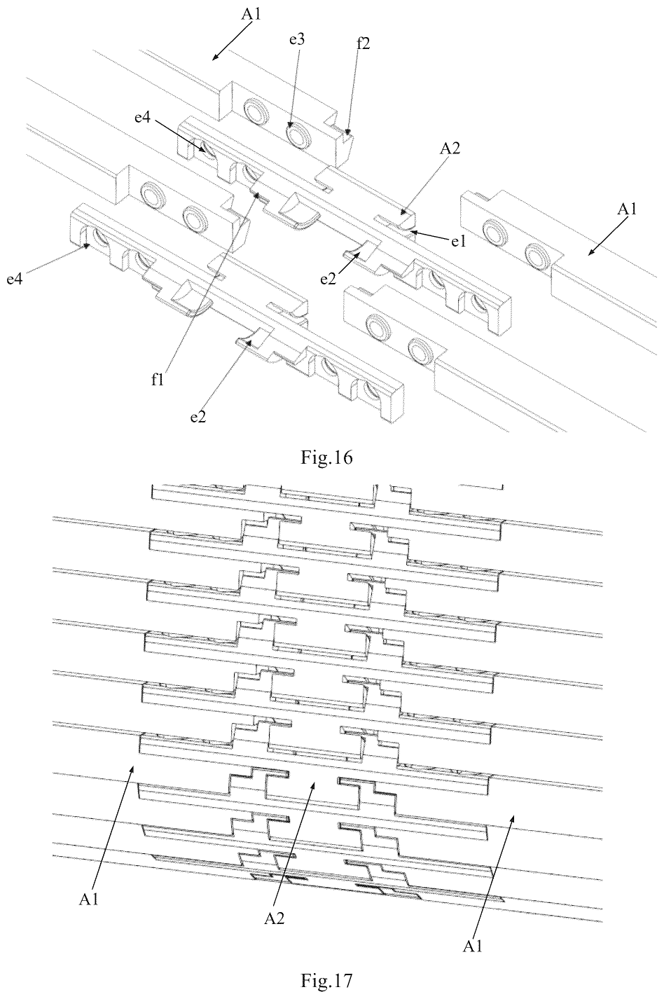

In this embodiment of the present disclosure, reference is made to FIG. 16 and FIG. 17. FIG. 16 is an exploded schematic diagram of a support bar body provided by this embodiment of the present disclosure, and FIG. 17 is a schematic diagram of a connection of the support bar body illustrated in FIG. 16. The support bar body A in the support bar 501 may include at least two sub-bar bodies A1 arranged in sequence along a length direction of the support bar body A, and a second connecting member A2 disposed between the two adjacent sub-bar bodies A1. The second connecting member A2 may be fixedly connected to each one end portion of the two adjacent sub-bar bodies A1, and two adjacent second connecting members A2 of the two adjacent support bars 501 are movably connected. In this case, at least two sub-bar bodies A1 are arranged in sequence in the support bar body A, and the second connecting member A2 is disposed between the two adjacent sub-bar bodies A1, and the two adjacent second connecting members A2 in the two adjacent support bars 501 are movably connected, such that a stable connection between the two adjacent support bars 501 is further realized by the cooperation of the first connecting member B and the second connecting member A2. It is to be noted that the sub-bar body A1 and the second connecting member A2 in the support bar body A may also be of a one-piece structure.

Optionally, as shown in FIGS. 16 and 17, the second connecting member A2 in the support bar 501 may have a second arc-shaped slide groove e1, and a second slider e2 that matches the shape of the second arc-shaped slide groove e1. For two second connecting members A2 in two adjacent support bars 501, at least part of the second slider e2 in one of the second connecting members A2 may be disposed within the second arc-shaped slide groove e1 in the other second connecting member A2. In this case, the second arc-shaped slide groove e1 and the second slider e2 that matches the shape of the second arc-shaped slide groove e1 are respectively arranged in the second connecting members A2, such that the second slider e2 in the second connecting member A2 in one of two adjacent support bars 501 may be disposed within the second arc-shaped slide groove e1 in the second connecting member A2 in the other support bar 501, and when the display device is switched between the unfolded state and the contracted state (during which the first support plate and the second support plate drive both the flexible display panel and the plurality of support bars to move), the second slider e2 can slide smoothly within the second arc-shaped slide groove e1.

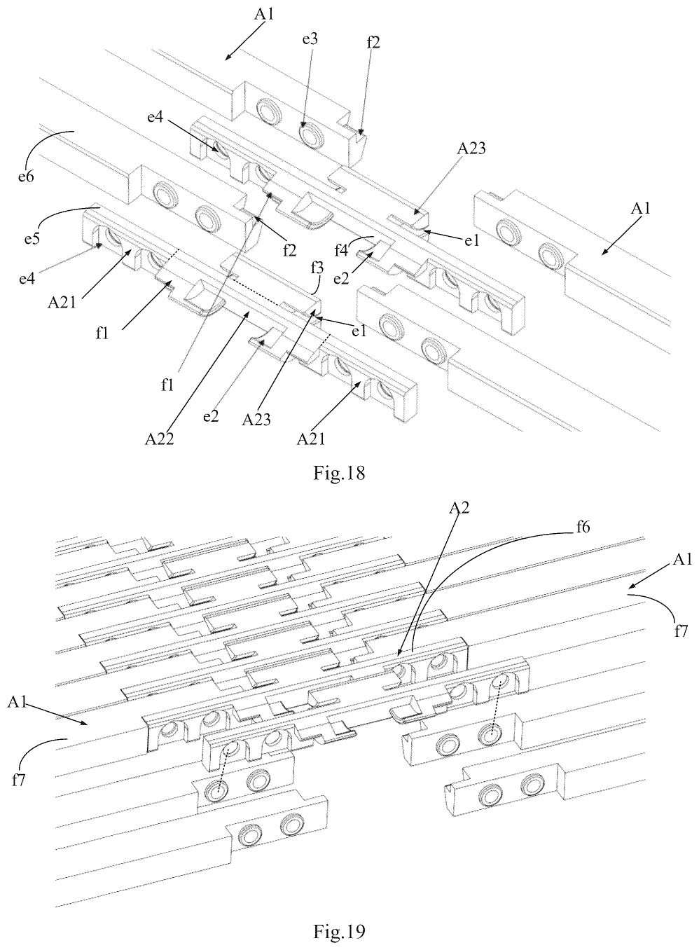

In an embodiment of the present disclosure, reference is made to FIG. 18, which is an exploded schematic diagram of a second connecting member and a sub-bar body provided by an embodiment of the present disclosure. The second connecting member A2 in each support bar body A may include two second connecting member bodies A21, a second connecting portion A22 disposed between the two second connecting member bodies A21, and a third raised portion A23 fixedly connected to one side of the second connecting portion A22 The second connecting member body A21 in the second connecting member A2 may be fixedly connected to an end portion of the sub-bar body A1 in the support bar body A close to the second connecting member A2. The third raised portion A23 in the second connecting member A2 may have a second arc-shaped slide groove e1, and the side of the second connecting portion A22 in the second connecting member A2 that is away from the third raised portion A23 may have a second slider e2. In this case, the third raised portion A23 is arranged on the side of the second connecting portion A22, the second arc-shaped slide groove e1 may be arranged in the third raised portion A23, and the second slider e2 is provided on the side of the second connecting portion A22 away from the third raised portion A23, such that when a part of the second slider e2 is disposed in the second arc-shaped slide groove e1 and slides in the second arc-shaped slide groove e1, the two second connecting members A2 in the two adjacent support bars 501 will not be detached from each other along the length direction of the support bars 501. In the present disclosure, as shown in FIG. 18, one of the second connecting member body A21 and the sub-bar body A1 may have a second positioning post e3, and the other may have a second positioning hole e4 cooperating with the second positioning post e3, and the second positioning hole e4 may be sleeved on the second positioning post e3. After the second connecting member body A21 is fixedly connected to the sub-bar body A1, the side e5 of the second connecting member body A21 facing the flexible display panel 600 may be flush with the side e6 of the sub-bar body A1 facing the flexible display panel 600. In this case, the cooperation of the second positioning post e3 and the second positioning hole e4 can ensure the positional accuracy of the second connecting member body A21 and the sub-bar body A1 during assembly and a support plane formed by the side es of the second connecting member body A21 facing the flexible display panel 600 and the side e6 of the sub-bar body A1 facing the flexible display panel 600 can effectively support the flexible display panel 600.

Optionally, as shown in FIG. 18, one side of the second connecting portion A22 of the second connecting member A2 away from the third raised portion A23 may also have a third limiting projection f1, and the end portion of the sub-bar body A1 close to the second connecting member A2 may have a limiting groove f2 that cooperates with the third limiting projection f1. When one side of both the support bar bodies A in the two adjacent support bars 501 facing the flexible display panel 600 can be flush with the side of the first support plate 300 facing the flexible display panel 600, or when one side of both the support bar bodies A in the two adjacent support bars 501 facing the flexible display panel 600 can be flush with the side of the second support plate 400 facing the flexible display panel 600, at least part of the third limiting protrusion f1 of one support bar 501 can be disposed in the limiting groove f2 of the other support bar 501, so as to abut against the end portion of the sub-bar body A1 in the other support bar 501 close to the second connecting member A2. In this case, after the switching of the display device between the unfolded state and the contracted state is completed, there is usually one side of both the support bar bodies A of two adjacent support bars of a part of the support bars in the plurality of support bars 501 facing the flexible display panel 600 are flush with the side of the first support plate 300 facing the flexible display panel 600 or, there is usually one side of both the support bar bodies A of two adjacent support bars of another portion of the support bars in the plurality of support bars 501 facing the flexible display panel 600 are flush with the side of the second support plate 400 facing the flexible display panel 600. During this switching process, the second slider e2 of one of the two adjacent support bars 501 slides in the counterclockwise direction within the second arc-shaped slide groove e1 in the other support bar 501, and when the second slider e2 slides to a third target position, the third limiting projection f1 in one support bar 501 is located in the limiting groove f2 in the sub-bar body A1 in the other support bar 501 so as to abut against the end portion of the sub-bar body A1 close to the second connecting member A2. When two adjacent support bars 501 are movably connected, if one support bar 501 is subjected to a force in a direction perpendicular to the flexible display panel 600, it is possible that the second slider e2 in one support bar 501 slides within the second arc-shaped slide groove e1 in the other support bar 501. However, the second slider e2 will not slide excessively with respect to the second arc-shaped slide groove e1, due to the locking effect of the third limit projection f1 and the limit recess f2.

In this embodiment of the present disclosure, as shown in FIG. 18, when both adjacent support bars 501 can be located on the side of the roller 200 away from the support shell 100, a side f3 of the third raised portion A23 away from the second connecting portion A22 in one of the support bars 501 can abut against the side f4 of the second connecting portion A22 away from the third raised portion A23 in the other support bar 501. In this case, when two adjacent support bars in yet another portion of the plurality of support bars 501 slide at the roller 200, the second slider e2 in one of the two adjacent support bars is able to slide in the clockwise direction within the second arc-shaped slide groove e1 in the other support bar, and when the second slider e2 slides to a fourth target position, a side f3 of the third raised portion A23 away from the second connecting portion A22 in one of the support bars 501 can abut against the side f4 of the second connecting portion A22 away from the third raised portion A23 in the other support bar 501, thereby ensuring that there is no excessive sliding between the second slider e2 and the second arc-shaped slide groove e1.

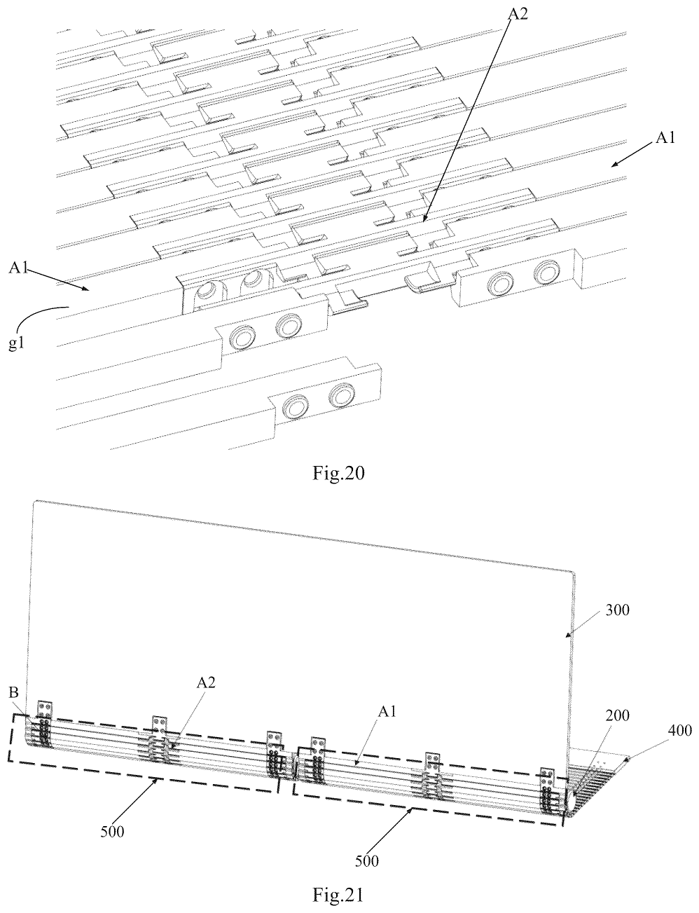

Optionally, reference is made to FIG. 19 and FIG. 20. FIG. 19 is an exploded schematic diagram of a partial structure of a plurality of support bar bodies provided by an embodiment of the present disclosure, and FIG. 20 is a partial structure of the plurality of support bar bodies illustrated in FIG. 19. A side f6 of the second connecting member A2 in the support bar body A facing the flexible display panel 600 may be flush with a side f7 of the sub-bar body A1 facing the flexible display panel 600. In this case, the side f6 of the second connecting member A2 in the support bar 501 facing the flexible display panel 600 is set to be flush with the side f7 of the sub-bar body A1 facing the flexible display panel 600, such that a support plane formed by the side f6 of the second connecting member A2 facing the flexible display panel 600 and the side f7 of the sub-bar body A1 facing the flexible display panel 600 can effectively support a back of the flexible display panel 600.

In an embodiment of the present disclosure, reference is made to FIG. 21, which is a schematic diagram of an arrangement of a plurality of track support assemblies provided by an embodiment of the present disclosure. Both the first connecting member B and the second connecting member A2 in the support bar closest to the first support plate 300 of the plurality of support bars 501 in the display device may be fixedly connected to the first support plate 300. The first connecting member B and the second connecting member A2 in the support bar closest to the second support plate 400 of the plurality of support bars 501 in the display device can both be fixedly connected to the second support plate 400. In the present disclosure, the first connecting member B in the support bar closest to the first support plate 300 of the plurality of support bars 501 in the display device may be fixed with the first support plate 300 by screw (not shown in the drawings), and the second connecting member A2 in the support bar closest to the first support plate 300 of the plurality of support bars 501 in the display device may also be fixed with the first support plate 300 by screw. The first connecting member B in the support bar closest to the second support plate 400 of the plurality of support bars 501 in the display device may be fixed with the second support plate 400 by screw, and the second connecting member A2 in the support bar closest to the second support plate 400 of the plurality of support bars 501 in the display device may be fixed with the second support plate 400 by screw.

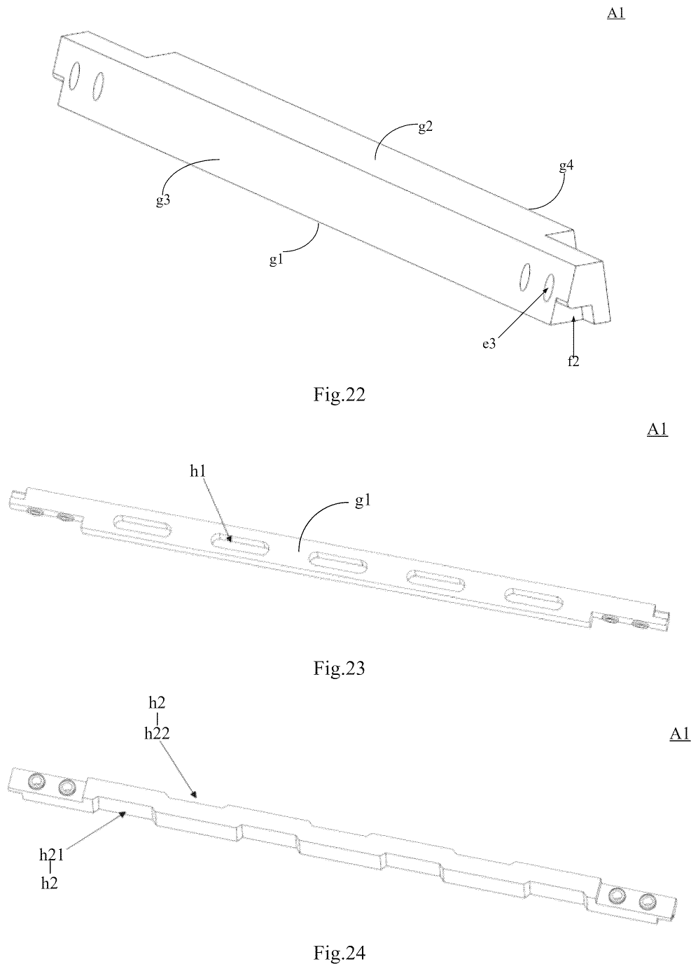

Optionally, reference is made to FIG. 22, which is a structural schematic diagram of a sub-bar body provided by an embodiment of the present disclosure. The sub-bar body A1 in the support bar 501 may have a first plane g1 and a second plane g2 disposed opposite to each other, and a third plane g3 and a fourth plane g4 disposed between the first plane g1 and the second plane g2 and are opposite to each other. The first plane g1 in the sub-bar body A1 may be the side of the sub-bar body A1 facing the flexible display panel 600 and the second plane g2 may be a side of the sub-bar body A1 that is away from the flexible display panel 600. An angle between the first plane g1 and the third plane g3 in the sub-bar body A1 may be an acute angle, and/or an angle between the first plane g1 and the fourth plane g4 in the sub-bar body A1 may be an acute angle. In the present disclosure, an angle between the first plane g1 and the third plane g3 of the sub-bar body A1 may be an acute angle; or, an angle between the first plane g1 and the fourth plane g4 of the sub-bar body A1 may be an acute angle; or, an angle between the first plane g1 and the third plane g3 of the sub-bar body A1 is an acute angle, and an angle between the first plane g1 and the fourth plane g4 of the sub-bar body A1 may also be an acute angle. In this way, the arrangement of the acute angle can effectively avoid an undesirable phenomenon that two adjacent sub-bar bodies A1 interfere with each other when sliding at the roller 200. Exemplarily, the angle range of the acute angle may be less than or equal to 20 degrees.

In the embodiments of the present disclosure, considering the problem the problem that the weight of the track support assembly 500 is relatively larger, the structure of the sub-bar body A1 in the support bar 501 is further designed in the embodiments of the present disclosure, and two optional implementations are taken as examples for schematic description as follows:

For a first optional implementation, refer to FIG. 23, which is a structural schematic diagram of another sub-bar body provided by an embodiment of the present disclosure. The sub-bar body A1 in the support bar 501 may have a plurality of lightening holes h1, which may pass through the first plane g1 and the second plane g2 in the sub-bar body A1. In this case, the weight of the track support assembly 500 can be effectively reduced by the plurality of lightening holes h1 arranged in the sub-bar body A1, thereby reducing the overall weight of the display device. In addition, the lightening holes h1 pass through the first plane g1 and the second plane g2 in the sub-bar body A1, so that a contact area between the flexible display panel 600 and the first plane g1 is reduced, thereby reducing the friction between the flexible display panel 600 and the track support assembly 500. It is to be noted that in other possible implementations, the lightening holes h1 in the sub-bar body A1 may also pass through the third plane g3 and the fourth plane g4 in the sub-bar body A1, which is not specifically limited in the embodiment of the present disclosure. Exemplarily, the plurality of lightening holes h1 in the sub-bar body A1 may be distributed at equal intervals, and the length and width of the lightening holes h1 may be set according to actual needs, which is not specifically limited in the embodiment of the present disclosure. The shape of the lightening holes h1 may be circular, rectangular or waist-shaped, which is not specifically limited in the embodiment of the present disclosure.

For a second optional implementation, please refer to FIG. 24, which is a structural schematic diagram of yet another sub-bar body provided by an embodiment of the present disclosure. The sub-bar body A1 in the support bar 501 may have a plurality of lightening grooves h2, and the plurality of lightening grooves h2 may be distributed on at least one of the first plane g1, the second plane g2, the third plane g3 and the fourth plane g4 in the sub-bar body A1. In this case, the weight of the track support assembly 500 can be effectively reduced by the plurality of lightening grooves h2 arranged in the sub-bar body A1, thereby reducing the overall weight of the display device. Exemplarily, a plurality of first lightening grooves h21 may be distributed on the first plane g1 in the sub-bar body A1, and a plurality of second lightening grooves h22 may be distributed on the second plane g2 in the sub-bar body A1, and the first lightening grooves h21 and the second lightening grooves h22 may be arranged at intervals. The plurality of first lightening grooves h21 on the first plane g1 in the sub-bar body A1 may be arranged at equal intervals, and the plurality of second lightening grooves h22 on the second plane g2 in the sub-bar body A1 may also be arranged at equal intervals. In this way, when the lightening grooves h2 are arranged on the first plane g1 of the sub-bar body A1, a contact area between the flexible display panel 600 and the sub-bar body A1 is reduced, thereby reducing the friction between the flexible display panel 600 and the track support assembly 500.

Optionally, as shown in FIG. 21, the display device may include a plurality of groups of track support assemblies 500, and the plurality of groups of track support assemblies 500 may be disposed in a length direction of the roller 200 in sequence. In this way, the arrangement of the plurality of groups of track support assemblies 500 in the display device can ensure that the span of a single group of track support assemblies in the plurality of groups of track support assemblies 500 is not too long, and avoid the undesirable phenomenon that the concentricity may be low due to a large number of second connecting members in the single group of track support assemblies. It is to be noted that the two ends in each group of track support assemblies 500 are movably connected by the first connecting member B, the middle portion is movably connected by the second connecting member A2, and the first connecting member B is connected to the second connecting member A2 by the sub-bar body A1.

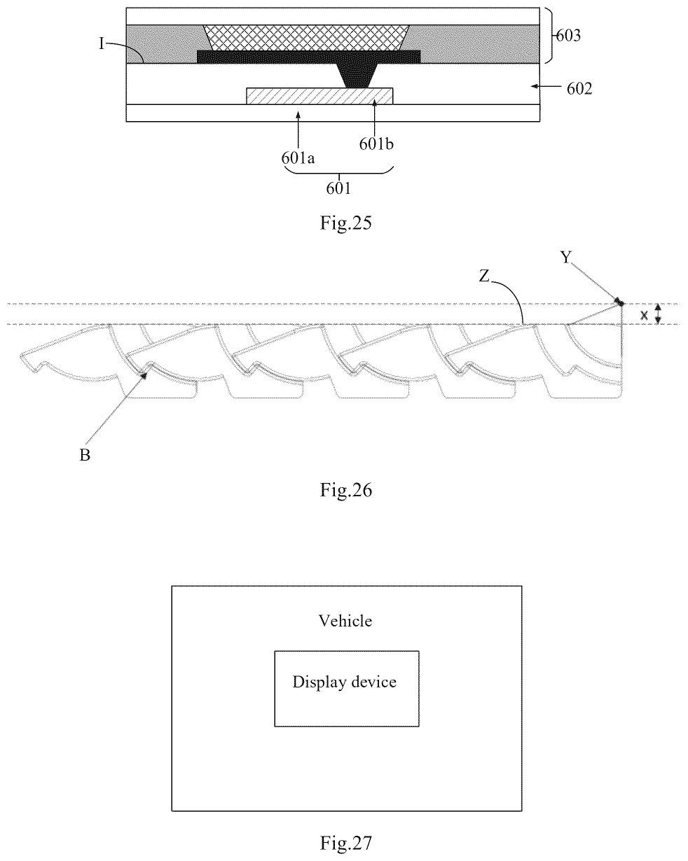

In an embodiment of the present disclosure, please refer to FIG. 25, which is a structural schematic diagram of a film layer of a flexible display panel provided by an embodiment of the present disclosure. The flexible display panel 600 may include a driving backplane 601, a planarization layer 602 disposed on one side of the driving backplane 601, and a plurality of light-emitting devices 603 disposed on a side of the planarization layer 602 away from the driving backplane 601, and each of the plurality of light-emitting devices 603 may be electrically connected to the driving backplane 601. In two adjacent support bars, one support bar can rotate relative to the other support bar, and a rotation axis rotation axis of one support bar when rotating relative to the other support bar may be located within the surface I of the planarization layer 602 away from the driving backplane 601. That is, a vertical distance between the rotation axis of one support bar 501 and the surface of the support bar 501 facing the flexible display panel 600 when the support bar 501 rotate relative to the other support bar 501 may be equal to the vertical distance between the surface of the planarization layer 602 away from the driving backplane 601 and the surface of the support bar 501 facing the flexible display panel 600. Therefore, it is ensured that the surface of the planarization layer away from the driving back plate is at the same position as the rotation axis of the one support bar when it is rotated relative to the other support bar, which effectively avoids the misalignment caused by the inner and outer diameters of the flexible display panel and the track support assembly when they slide at the roller, and ensures that the display effect of the flexible display panel is better. It is to be noted that the rotation axis of one support bar relative to another support bar through the first connecting member is the same as the rotation axis of one support bar relative to another support bar through the second connecting member are. In the present disclosure, the driving backplane 601 may include a flexible substrate 601a, and a plurality of driving circuits 601b disposed on the side of the flexible substrate 601a close to the planarization layer 602, and the driving circuits 601b are used to drive the light-emitting device 603 to work.

Exemplarily, first connecting members are taken as an example, please refer to FIG. 25 and FIG. 26. FIG. 26is a side view of a plurality of connected first connecting members provided by an embodiment of the present disclosure. In two adjacent first connecting members B, a distance between a rotation axis Y of one first connecting member B relative to the other first connecting member B and a support surface Z of the track support assembly (i.e., the surface of the support bar body connected to the first connecting members facing the flexible display panel) is x, and a distance between the surface I of the planarization layer 602 that is away from the driving backplane 601 and the support surface Z of the track support assembly is also x.

Optionally, the display device may further include a drive assembly (not shown in the figures), which may be fixed within the support shell 100 and the drive assembly may be coupled to at least one of the first support panel 300 and the second support panel 400. Exemplarily, the drive assembly may be fixed within the first shell 101 and connected to a side of the first support plate 300 that is away from the flexible display panel 600. The drive assembly may be configured to drive the first support plate in a direction perpendicular to the roller. In this case, by providing the drive assembly in the display device, the first support plate can be driven to move by the drive assembly, so that the track support assembly and the flexible display panel are driven to move, and the automation degree of the display device is improved. In the present disclosure, the display device further includes a control component (not shown in the drawings) electrically connected to the drive assembly, and the control component can control the drive assembly to carry out normal operation after receiving the driving instruction. Exemplarily, the drive assembly may include a driving motor and a transmission component, the transmission component is connected to the first support plate and the driving motor respectively, and the driving motor drives the first support plate to move through the transmission component.

In summary, the embodiments of the present disclosure provide a display device that may include a support shell, a roller, a first support plate, a second support plate, at least one group of track support assemblies, and a flexible display panel. A plurality of support bars are movably connected in sequence between the first support plate and the second support plate in the display device. A first planar display portion of the flexible display panel is fixedly connected to the first support plate and a second planar display portion is fixedly connected to the second support plate. The plurality of support bars disposed between the two support plates can effectively support a back of the flexible display panel and effectively reduce the probability of undesirable phenomenon of unevenness of the flexible display panel, so that the overall flatness of the flexible display panel is better and then the display effect of the display device is better. In addition, there exists a part of the support bars distributed on the side of the roller away from the support shell, and the curled display portion in the flexible display panel is in contact with the part of the support bars and is detachably arranged. In this way, when the flexible display panel is switched between the unfolded state and the contracted state, no dislocation stress is generated between the support bars and the curled display portion in the flexible display panel. That is, a pulling force caused by misalignment between the support bar and the flexible display panel when the support bar and the flexible display panel slide at the roller (the rotation radii of the support bar and the flexible display panel are different, and there may be a phenomenon of inconsistent rotation paths) is effectively avoided, so that the use reliability of the flexible display panel in the display device is ensured.

Embodiments of the present disclosure also provide a vehicle, refer to FIG. 27, which is a block diagram of a vehicle provided by an embodiment of the present disclosure. The vehicle may include a display device fixed within a cabin of the vehicle, which may be a display device given in any of the above. Exemplarily, the transportation vehicle may be a tool with a transport function such as a vehicle or a ship, and the display device may be fixed in a cockpit or a passenger compartment of the tool of transportation. For example, the display device may be fixed to a vehicle dashboard, a roof, or a seat in the driver's compartment of the vehicle.

It is noted that in the accompanying drawings, the dimensions of the layers and regions may be exaggerated for the sake of clarity of illustration. Moreover, it is understood that when an element or layer is referred to as being “on” another element or layer, it may be directly on the other element or there may be intervening layers. Also, it can be understood that when the element or layer is referred to as being “under” another element or layer, it can be directly under the other element, or more than one intermediate layer or element can exist. It is also understood that when a layer or element is referred to as being “between” two layers or elements, it may be the only layer between the two layers or elements, or there may be more than one intermediate layer or element. Similar reference marks throughout indicate similar elements.

In the present disclosure, the terms “first” and “second” are used for descriptive purposes only and are not to be understood as indicating or implying relative importance. The term “plurality” refers to two or more, unless otherwise expressly limited.

The foregoing are only optional embodiments of the present disclosure and are not intended to limit the present disclosure, and any modifications, equivalent substitutions, improvements, etc., made within the spirit and principles of the present disclosure shall be included in the scope of protection of the present disclosure.

1. A display device, comprising:
a support shell, wherein the support shell comprises a first shell and a second shell, the first shell and the second shell are connected to each other, and an angle between the first shell and the second shell is less than 180°;
a roller, wherein the roller is disposed between the first shell and the second shell, and the roller is rotatably connected to the support shell;
a first support plate slidably connected to the first shell;
a second support plate slidably connected to the second shell;
at least one group of track support assemblies, wherein each of track support assemblies comprises a plurality of support bars arranged in an array between the first support plate and the second support plate, the plurality of support bars are movably connected in sequence, two outermost support bars of the plurality of support bars are fixedly connected to the first support plate and the second support plate respectively, and at least part of the plurality of support bars are disposed on a side of the roller away from of the support shell; and
a flexible display panel, wherein the flexible display panel comprises a first planar display portion and a second planar display portion, and a curled display portion disposed between the first planar display portion and the second planar display portion, the first planar display portion is fixedly connected to the first support plate, the second planar display portion is fixedly connected to the second support plate, and the curled display portion is in contact with at least part of the plurality of support bars but is not connected to the at least part of the plurality of support bars.

2. The display device according to claim 1, wherein each of the plurality of support bars comprises a support bar body, and a first connecting member fixedly connected to each end portion of the support bar body; and
wherein two adjacent first connecting members in two adjacent support bars are movably connected.

3. The display device according to claim 2, wherein the first connecting member comprises a first arc-shaped slide groove, and a first slider matching a shape of the first arc-shaped slide groove; and
wherein, for the two adjacent first connecting members, at least part of the first slider of one first connecting member is disposed within the first arc-shaped slide groove of the other first connecting member.

4. The display device according to claim 3, wherein the first connecting member comprises a first connecting member body, a first raised portion, a second raised portion and a first connecting portion;
the first connecting member body is fixedly connected to an end portion of the support bar body; the first raised portion and the second raised portion are both fixedly connected to a side of the first connecting member body away from the support bar body, and the first arc-shaped slide groove is disposed between the first raised portion and the second raised portion; the first connecting member portion is fixedly connected to a side of the first raised portion away from the second raised portion; and the first connecting portion comprises the first slider on a side of the first connecting portion close to the support bar body; and
wherein, for the two adjacent first connecting members, the second raised portion in one first connecting member is disposed between the first slider and the first raised portion in the other first connecting member.

5. The display device according to claim 4, wherein a first limiting protrusion is disposed on a side, close to the second raised portion, of the first raised portion, and a second limiting protrusion is disposed on a side, away from the first raised portion, of the first connecting portion; and
wherein in a case that a side of each of support bar bodies in two adjacent support bars facing the flexible display panel is flush with a side of the first support plate facing the flexible display panel, or is flush with the second support plate facing the flexible display panel, a first limiting protrusion in one support bar abuts against a second limiting protrusion in the other support bar.

6. The display device according to claim 5, wherein a surface of the first raised portion facing the second raised portion comprises a first cambered surface and a second cambered surface, and a surface of the second raised portion close to the first raised portion is a third cambered surface; and
wherein the first arc-shaped slide groove is disposed between the first cambered surface and the third cambered surface and the second cambered surface is closer to the second raised portion than the first cambered surface.

7. The display device according to claim 6, wherein
a surface of the second limiting protrusion away from the first raised portion is flush with a surface of the first slider away from the first raised portion; and
for the two adjacent first connecting members, the surface of the second limiting protrusion in one first connecting member that is away from the first raised portion and the surface of the first slider that is away from the first raised portion both abut against the first cambered surface of the first raised portion in the other first connecting member.

8. The display device according to claim 6, wherein the first connecting portion comprises a fourth cambered surface that cooperates with the second cambered surface; and
wherein, for the two adjacent first connecting members, the second cambered surface of the first raised portion in one first connecting member abuts against the fourth cambered surface of the first connecting portion in the other first connecting member.

9. The display device according to claim 4, wherein in a case that two adjacent support bars are both disposed on a side of the roller away from the support shell, a side of the first raised portion of one support bar facing the first connecting portion abuts against a side of the first raised portion of the other support bar away from the first connecting portion; and a side of the first connecting portion of one of the two adjacent support bars facing the flexible display panel is flush with a side of the first connecting member of the other of the two adjacent support bars facing the flexible display panel.

10. (canceled)

11. The display device according to claim 2, wherein the support bar body comprises at least two sub-bar bodies arranged in sequence along a length direction of the support bar body, and a second connecting member disposed between the at least two adjacent sub-bar bodies, and the second connecting member is fixedly connected to an end portion of each of the at least two adjacent sub-bar bodies; and
wherein two adjacent second connecting members in the two adjacent support bars are movably connected.

12. The display device according to claim 11, wherein the second connecting member comprises a second arc-shaped slide groove, and a second slider matching a shape of the second arc-shaped slide groove; and
wherein, for the two adjacent second connecting members, at least part of the second slider in one second connecting member is disposed within the second cambered slide groove in the other second connecting member.

13. The display device according to claim 12, wherein the second connecting member comprises two second connecting member bodies, a second connecting portion disposed between the two second connecting member bodies, and a third raised portion fixedly connected to one side of the second connecting portion; and
the second connecting member body is fixedly connected to an end portion of the sub-bar body close to the second connecting member; the second arc-shaped slide groove is disposed in the third raised portion, and the second slider is disposed on a side of the second connecting portion away from the third raised portion.

14. The display device according to claim 13, wherein the side of the second connecting portion away from the third raised portion further comprises a third limiting projection, and the end portion of the sub-bar body close to the second connecting member comprises a limiting groove; and
wherein in a case that the side of each of the support bar bodies in the two adjacent support bars facing the flexible display panel is flush with the side of the first support plate facing the flexible display panel, or is flush with the side of the second support plate facing the flexible display panel, at least part of the third limiting projection in one support bar is disposed in a limiting groove in the other support bar so as to abut against the end portion of the sub-bar body in the other support bar close to the second connecting member.

15. The display device according to claim 13, wherein in a case that the two adjacent support bars are both disposed on a side of the roller away from the support shell, a side of the third raised portion of one support bar away from the second connecting portion abuts against a side of the second connecting portion of the other support bar away from the third raised portion.

16. The display device according to claim 12, wherein a side of the second connecting member facing the flexible display panel is flush with a side of the sub-bar body facing the flexible display panel.

17. The display device according to claim 12, wherein a first connecting member and a second connecting member of a support bar of the plurality of support bars which is closest to the first support plate are both fixedly connected to the first support plate, and a first connecting member and a second connecting member of a support bar of the plurality of support bars which is closest to the second support plate are both fixedly connected to the second support plate.

18. The display device according to claim 12, wherein the sub-bar body comprises a first plane and a second plane disposed opposite to each other, and a third plane and a fourth plane disposed between the first plane and the second plane and disposed opposite to each other;
wherein the first plane is a surface of the sub-bar body facing the flexible display panel, an angle between the first plane and the third plane is an acute angle, and/or an angle between the first plane and the fourth plane is an acute angle;
wherein the sub-bar body comprises a plurality of lightening holes, and the plurality of lightening holes pass through the first plane and the second plane; and
wherein the sub-bar body has a plurality of lightening grooves, and the plurality of lightening grooves are distributed on at least one of the first plane, the second plane, the third plane, or the fourth plane.

19.-20. (canceled)

21. The display device according to claim 1, wherein the display device comprises a plurality of groups of track support assemblies, and the plurality of groups of the track support assemblies are disposed in a length direction of the roller in sequence.

22. The display device according to claim 1, wherein the flexible display panel comprises a driving backplane, a planarization layer disposed on a side of the driving backplane, and a plurality of light-emitting devices disposed on a side of the planarization layer away from the driving backplane, and the plurality of light-emitting devices are electrically connected to the driving backplane; and
wherein, in two adjacent support bars, one support bar is rotatable relative to the other support bar, and in a case that one support bar rotates relative to the other support bar, a rotation axis of the support bar is within a surface of the planarization layer away from the driving backplane.

23. (canceled)

24. A vehicle, comprising: a display device fixed in a cabin of the vehicle, wherein the display device is the display device as defined in claim 1.
